(19) United States
(12) Patent Application Publication
(10) Pub. No.: US 2006/0076160 A1
(43) Pub. Date: Apr. 13, 2006

(54) Multilayer printed circuit board

(75) Inventors: Shou-Kuo Hsu, Tu-Cheng (TW); Yu-Chang Pai, Tu-Cheng (TW); Cheng-Hong Liu, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/247,341

(22) Filed: Oct. 11, 2005

(30) Foreign Application Priority Data
Oct. 9, 2004 (CN) 200410051838.X

(51) Int. Cl. H05K 1/11

(52) U.S. Cl. 174/262; 29/846

(57) ABSTRACT

A multilayer printed circuit board (PCB) includes a plurality of signal planes, two reference planes, a signal via, and a stitching via. The signal via passes through all planes for a signal trace flowing therethrough. The stitching via is defined near the signal via and electrically connects to one of the reference plane. The stitching via serves as a stitching capacitor, to reduce the area of the signal current flows in the PCB, even to control crosstalk and lower the noise on the PCB. It is of advantage that the stitching via is simple to manufacture and very suitable for mass production.

### BACKGROUND OF THE INVENTION

1. Field of the Invention

The present invention relates to printed circuit boards, and particularly to a multilayer printed circuit board that can maintain signal integrity.

2. General Background

Multilayer printed circuit boards (PCBs) are commonly used in electronic devices to connect electronic components such as integrated circuits to one another. A typical multilayer PCB includes many layers of copper, with each layer of copper separated by a dielectric material. Generally, several of the copper layers are used to provide a reference voltage plane or ground plane. In addition, several layers of the copper are etched to form the traces that connect individual components. Vias in a multilayer PCB provide layer-to-layer interconnections. Copper lined through vias extend though the layers of the PCB to selectively connect the electronic components on the surface of the PCB to the reference planes and traces within the PCB and to selectively connect copper is traces on different layers to one another.

Referring to FIG. 3, a 4-layer printed circuit board is provided. The 4-layer printed circuit board 100 includes a first signal plane 1, a power plane 2, a ground plane 3, and a second signal plane 4. A signal trace 6 is lined through a signal via 8 for changing from the first signal plane 1 to the second signal plane 4. If there have no decoupling capacitance on the PCB, displacement current would flow between the power plane 1 and the ground plane 4 to enable the return current 11 to flow on the power plane 2, thus causing noise in the power plane 2 and the ground plane 4. When there are more than two traces to be routed in the PCB, significant amount of noise generation, crosstalk problem may occur.

FIG. 4 showns a modified version of the 4-layer PCB 100, referred to as a 4-layer PCB 200, which is structurally similar to the 4-layer PCB 100 except that a stitching capacitor 15 is coupled between the power plane 2 and the ground plane 3, thereby forming a return current path. A new return current 12 flows along a bottom surface of the ground plane 3 and through the signal via 8 to the top surface of the power plane 2, then the return current 12 flows via the stitching capacitor 15 and along a bottom surface of the power plane 2 to the signal via 8, finally to a top surface of the first signal plane 1. When the impedance of the stitching capacitor 15 is lower than that of the displacement current, the return current 12 flows mainly through the stitching capacitor 15, to avoid significant amount of noise. However, some of the return currents change to common-mode currents to flow on the top surface of the power plane 2, result in radiation. The stitching capacitor 15 is in no use when interplane capacitance between the power and the ground plane is so small that lower than the stitching capacitor. Further, employing the stitching capacitor increases the cost of making the PCB.

It is therefore apparent that a need exits to provide a multilayer PCB that not only attenuates noise and crosstalk of signals, but also can be mass produced at a reasonable cost.

### SUMMARY

A multilayer printed circuit board (PCB) includes a plurality of signal planes, two reference planes, a signal via, and a stitching via. The signal via passes through all planes for a signal trace flowing therethrough. The stitching via having electrically conductive pieces is defined near the signal via and electrically connects to one of the reference plane.

The stitching via serves as a stitching capacitor, to reduce the area of the signal current flowes in the PCB, even to control crosstalk and lower the noise on the PCB. It is of advantage that the stitching via is simple to manufacture and very suitable for mass production.

Other advantages and novel features will become more apparent from the following detailed description when taken in conjunction with the accompanying drawings, in which:

### BRIEF DESCRIPTION OF THE DRAWINGS

FIG. 1 is a printed circuit board in accordance with a first preferred embodiment of the preset invention;

FIG. 2 is a printed circuit board in accordance with a second preferred embodiment of the preset invention;

FIG. 3 is the current trace in a conventional printed circuit board; and

FIG. 4 is the current trace when a stitching capacitor is defined in the printed circuit board.

### DETAILED DESCRIPTION OF THE EMBODIMENTS

In a PCB, electric field strength E can be approximately estimated as follows:
E=2.6(AI_{L}f²) (1)
wherein A denotes a loop area of a signal current in the PCB, I_{L} denotes a current carried by a signal, and f is frequency of the signal. The electric field strength and the loop area of the signal current are directly proportional to each other. The smaller the electric field is, the smaller the noise and crosstalk of the PCB will be. It can be deduced that to decrease the electric field strength, the loop area of the signal current should preferably be decreased, too.

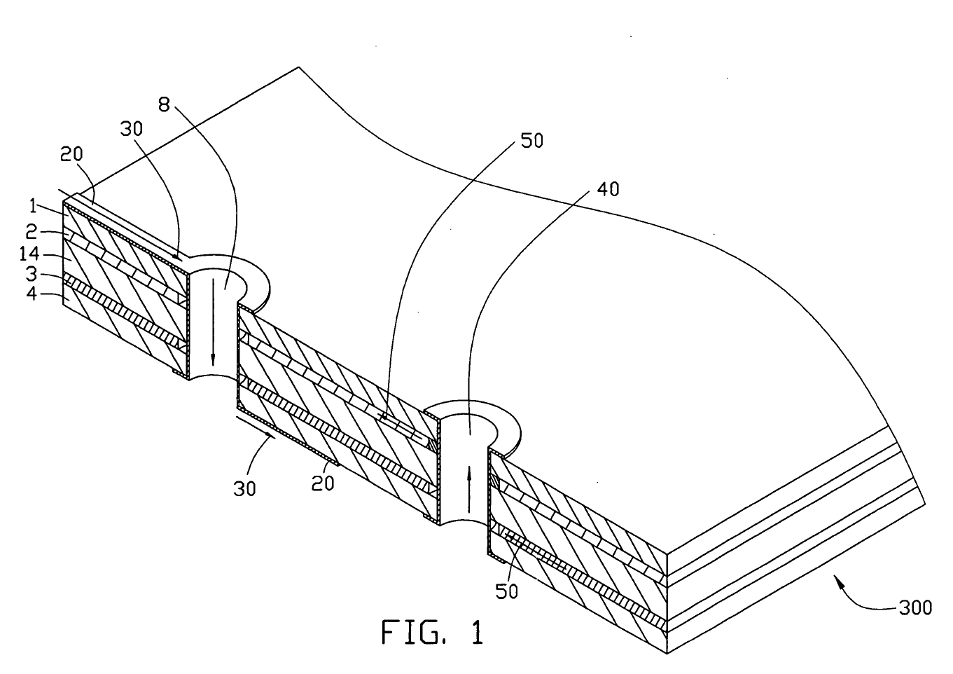

Referring to FIG. 1, a printed circuit board (PCB) 300 according to a first embodiment of the present invention is provided. The PCB 300 includes a first signal plane 1, a power plane 2, a ground plane 3, and a second signal plane 4. A plurality of dielectric material layers 14 is inserted among the first signal plane 1, the power plane 2, the ground plane 3, and the second signal plane 4. In FIG. 1, only the dielectric material layer 14 between the power plane 2 and the ground layer 3 is shown. The power plane 2 or the ground plane 3 is usually taken as reference plane. A signal trace 20 is routed from the top surface of the first signal plane 1 to a signal via 8 which passes through all layers of the PCB 300. The signal via 8 is not electrically connected to the power plane 2 and the ground plane 3. At the signal via 8, the signal trace 20 dives down through layers stack, and then runs along the under surface of the second signal plane 4. Arrows 30 on the signal trace 20 indicate a “go” direction in which signal current moves. A stitching via 40 having electrically conductive pieces therein is defined in the PCB 300 and resides parallel to the signal via 8. The stitching via 40 resides near from the signal via 8, and the stitching via 40 is a conductor and electrically connected to the power plane 2. A return current 50 for the signal trace 20 therefore runs from the bottom surface of the ground plane 3 through the stitching via 40 to the top surface of the power plane 2, to form a galvanic circle. The area of the loop of the signal current formed in the PCB 300 is smaller than in the PCB 200 (related art shown in FIG. 4) to control crosstalk and lower the noise on the PCB.

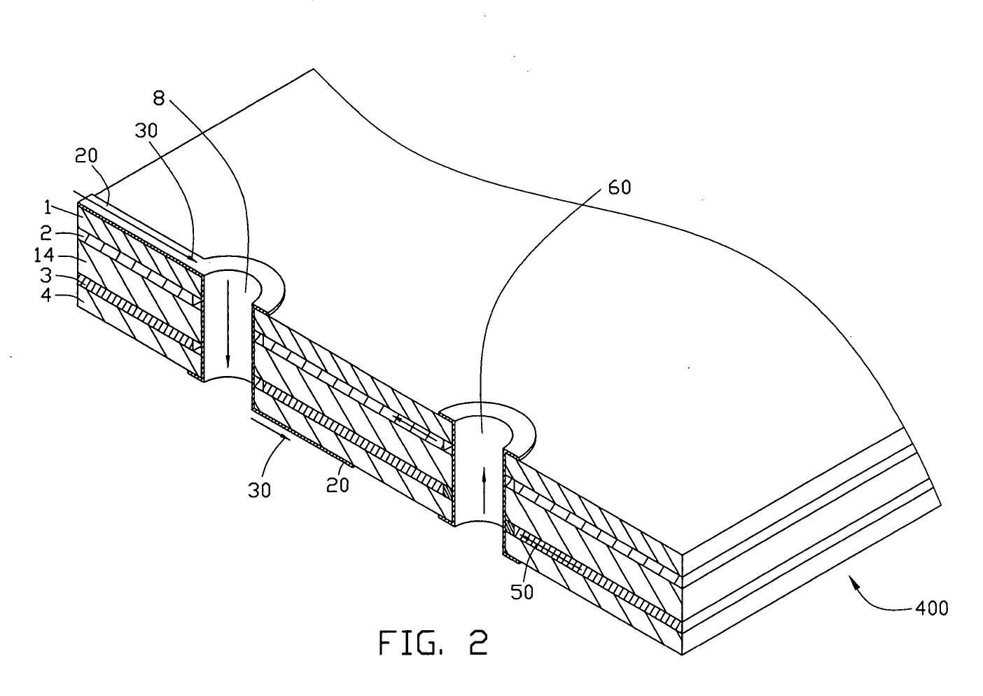

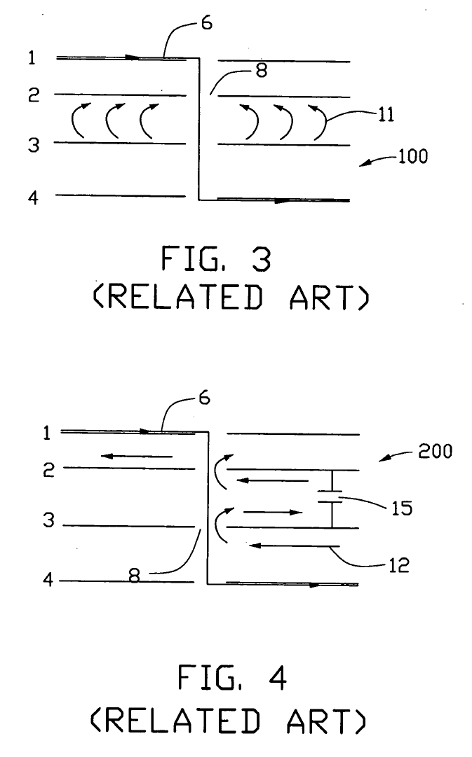

FIG. 2 is a PCB 400 of a second preferred embodiment of the present invention. A PCB 400 of the second embodiment is similar to the PCB 300 of the first embodiment. However, instead of having a stitching via 40 defined in the PCB 300, the PCB 400 has a stitching via 60 residing near from the signal via 8. The stitching via 60 is a conductor and electrically connected to the ground plane 3. A return current 50 for the signal trace 20 therefore runs from the bottom surface of the ground plane 3 through the stitching via 60 to the top surface of the power plane 2, the return current 50 and the go current form a galvanic circle. The area of the loop of the signal current formed in the PCB 300 is smaller than that in the PCB 200 (related art) to control crosstalk and lower the noise on the PCB.

The present invention can also be applied to multilayer PCBs such as a 6-layer PCB or a 8-layer PCB. The stitching via is just electrically connected to the reference plane (power plane or the ground plane). However, the stitching via can not be short-circuit with the power plane and the ground plane at the same time.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A multilayer printed circuit board (PCB) comprising:
a plurality of signal planes;
a plurality of reference planes;
a signal via passing through the signal planes and said reference planes for a signal current flowing therethrough; and
a stitching via defined near the signal via and electrically connected to one of said reference planes.

2. The printed circuit board as claimed in claim 1, wherein the stitching via is defined parallel to the signal via.

3. The printed circuit board as claimed in claim 1, wherein one of said reference planes electrically connected to the stitching via is a power plane.

4. The printed circuit board as claimed in claim 1, wherein one of said reference planes electrically connected to the stitching via is a ground plane.

5. The printed circuit board as claimed in claim 1, being a 4-layer PCB.

6. The printed circuit board as claimed in claim 1, being a 6-layer PCB.

7. The printed circuit board as claimed in claim 1, being an 8-layer PCB.

8. A multilayer printed circuit board (PCB) comprising:
at least one signal plane, adapted to place a signal trace thereto;
a power plane;
a ground plane;
a signal via passing through said signal plane, the power plane, and the ground plane for signal currents flowing therethrough; and
a stitching via defined near the signal via, the stitching via being electrically connected to one of the power plane and the ground without being electrically connected to the other of the power plane and the ground plane.

9. A method to manufacture a multilayer printed circuit board (PCB), comprising the steps of:
placing a signal trace respectively on a first signal plane of a multilayer printed circuit board (PCB) and a second signal plane of said PCB which is spaced from said first signal plane in said PCB;
electrically connecting said signal trace on said first signal plane and said signal trace on said second signal plane;
placing at least two reference planes having a respective voltage charge thereon different from each other between said first and second signal planes in said PCB so that at least one of said at least two reference planes is adapted to be located next to said signal trace on said first signal plane and said signal trace on said second signal plane respectively; and
configuring an electrically conductive piece next to said at least two reference planes so as to electrically connect with one of said at least two reference planes and to be spaced from others of said at least two reference planes in order for diminishing noise in said signal trace due to any of said at least two reference planes.

10. The method as claimed in claim 9, wherein said electrically conductive piece is a part of a via of said PCB installed near electrical connection of said signal trace between said first and second signal planes.
